(19) United States
(12) Patent Application Publication
(10) Pub. No.: US 2015/0137083 A1
(43) Pub. Date: May 21, 2015

(54) CONJUGATED AROMATIC DERIVATIVES AND ORGANIC LIGHT EMITTING DIODE USING THE SAME

(71) Applicant: National Tsing Hua University, Hsinchu (TW)

(72) Inventors: Chien-Hong CHENG, Hsinchu (TW); Chih-Chun LIN, Hsinchu (TW)

(73) Assignee: National Tsing Hua University, Hsinchu (TW)

(21) Appl. No.: 14/254,300

(22) Filed: Apr. 16, 2014

(30) Foreign Application Priority Data
Nov. 19, 2013 (TW) 102142017

(51) Int. Cl. H01L 51/00; H01L 51/50

(52) U.S. Cl. CPC H01L 51/0059; H01L 51/0072; H01L 51/5056; H01L 51/5072; H01L 51/5012
USPC 257/40; 564/15; 564/430; 548/414; 548/444; 548/301.7

(57) ABSTRACT

Conjugated aromatic derivatives having an electron donating group and an electron accepting group at each end are provided. The conjugated aromatic derivatives of the present invention may be provided with blue light-emitting property and may be applied as a host material, a dopant material, an electron transporting material or a hole transporting material. An OLED device using the conjugated aromatic derivatives is also herein disclosed.

### BACKGROUND OF THE INVENTION

1. Field of the Invention

The present invention relates to a conjugated aromatic derivative and an organic light emitting diode (OLED), and more particularly to a conjugated aromatic derivative having an electron donating group and an electron accepting group at each end and organic light emitting diode using the same.

2. Description of the Prior Art

OLED (organic light-emitting diode), also commonly known as organic electroluminescent device, is a kind of LED having an organic layer as the active layer. OLED has been spotlighted due to a lot of advantages, such as self illumination, wider visual angle (>170°), shorter response time (˜μs), higher contrast, higher efficiency, lower power consumption, higher brightness, lower operative voltage (3-10V), thinner size (<2 mm), flexibility and so on. In recent years, OLED has been gradually used in flat panel display. In comparison to LCD monitor, OLED displays are provided with OLED pixel array having self-luminous characteristics and therefore do not require additional back light module. To apply OLED into a full-color display, it is necessary and important to develop red, green, and blue light emitting materials with appropriate chromaticity and high light-emitting efficiency.

Excitons generated from recombining holes and electrons have triplet state or singlet state for its spin state. Singlet exciton relaxation radiates fluorescence and triplet exciton relaxation radiates phosphorescence. Phosphorescence achieves 3-fold efficiency comparing to fluorescence and may greatly enhance the IQE (internal quantum efficiency) of devices up to 100% by adopting metal complexes in electroluminescent configuration to achieve strong spin-orbital coupling and mixing of singlets and triplets. Therefore, phosphorescent metal complexes are now adopted as phosphorescent dopants in the emitting layer of OLED.

In addition, by using a doping method in the emitting layer, self-quenching of the emitting materials can be reduced greatly to enhance the efficiency of the device. Therefore, the search for proper host materials becomes noteworthy since host materials must be capable of capturing carriers and have good energy transfer properties, high glass transition temperature, high thermal stability and appropriate energy gap of the singlet and triplet excited states. However, it would be difficult to search for host materials that fully meet the criteria and there is still some room for host material development in OLED.

The hunt for efficient blue electroluminescence is of particular interest because it is an essential component to realize OLEDs in display as well as lighting applications. Many research groups have successfully prepared efficient blue fluorophores and their OLEDs. However, at the present time, the efficient ones with good Commission Internationale d'Enclairage y coordinate value (CIE_{y})≦0.15 are still relatively rare. At the present time, there is a lack of good organic electroluminescence compounds that will satisfy the aforementioned need.

To sum up, it is highly desirable to develop novel and efficient electroluminescent materials in blue color spectrum.

### SUMMARY OF THE INVENTION

The present invention is directed to providing novel conjugated aromatic derivatives.

According to one embodiment, a conjugated aromatic derivative having a chemical formula represented by formula (I):

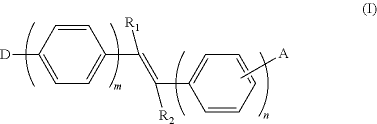

Here, m is an integer ranging from 0 to 5, n is an integer ranging from 0 to 5, each of R1 and R2 is independently selected from the group consisting of hydrogen, C₁ to C₆ alkyl group, aryl group.

When n=1 to 5, substituent A is selected from the group consisting of substituted or unsubstituted pyrene, substituted or unsubstituted phosphine oxide, substituted or unsubstituted sulfonyl and substituted or unsubstituted benzothiadiazole.

When n=0, substituent A is substituted or unsubstituted benzothiadiazole.

When m=1 to 5, substituent D is selected from the group consisting of substituted or unsubstituted amino group, substituted or unsubstituted imidazole, substituted or unsubstituted carbazole and substituted or unsubstituted

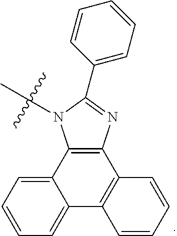 [SMILES: *n1c(-c2ccccc2)nc2c3ccccc3c3ccccc3c21]

When m=0, substituent D is substituted or unsubstituted

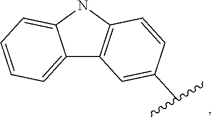 [SMILES: *c1ccc2[nH]c3ccccc3c2c1]

substituted or unsubstituted

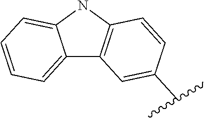 [SMILES: *c1ccc2[nH]c3ccccc3c2c1]

or, substituted or unsubstituted

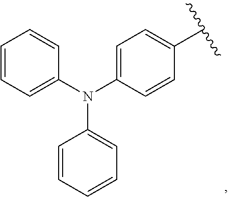 [SMILES: *c1ccc(N(c2ccccc2)c2ccccc2)cc1]

wherein each of the substituents of substituent D or substituent A is independently selected from the group consisting of halogen, aryl group, C₁-C₂₀ alkenyl, C₁-C₂₀ alkyl, C₁-C₂₀ alkynyl, cyano, CF₃, alkylamino, amino, alkoxy, heteroaryl, halogen substituted aryl group, halogen substituted aralkyl group, haloalkyl substituted aryl group, haloalkyl substituted aralkyl group, aryl substituted C₁-C₂₀ alkyl group, cycloalkyl group, C₁-C₂₀ alkoxy group, C₁-C₂₀ alkyl substituted amino group, haloalkyl substituted amino group, aryl substituted amino group, heteroaryl substituted amino group, aryl substituted phosphine oxide, C₁-C₂₀ alkyl substituted phosphine oxide, haloalkyl substituted phosphine oxide, halogen substituted phosphine oxide, heteroaryl substituted phosphine oxide, nitro group, carbonyl group, aryl substituted carbonyl group, heteroaryl substituted carbonyl group and halogen substituted C₁-C₂₀ alkyl group.

The present invention is also directed to providing an OLED device with high efficiency and performance.

According to another embodiment, an organic light emitting diode includes a cathode, an anode and an organic layer configured between the cathode and the anode and comprising the aforementioned conjugated aromatic derivative.

The conjugated aromatic derivative of the present invention may be provided with blue light-emitting property and used as a host emitter material or a guest emitter material. The conjugated aromatic derivative of the present invention may also be configured as an electron transport material or a hole transport material.

Other advantages of the present invention will become apparent from the following descriptions taken in conjunction with the accompanying drawings wherein certain embodiments of the present invention are set forth by way of illustration and examples.

### BRIEF DESCRIPTION OF THE DRAWINGS

The foregoing aspects and many of the accompanying advantages of this invention will become more readily appreciated as the same becomes better understood by reference to the following detailed descriptions, when taken in conjunction with the accompanying drawings, wherein:

FIG. 1 is a schematic diagram illustrating an organic light emitting device containing conjugated aromatic derivatives according to one embodiment of the present invention.

### DESCRIPTION OF THE PREFERRED EMBODIMENT

The present invention is directed to providing a conjugated aromatic derivatives used as blue fluorescent material having a chemical formula represented by formula (I):

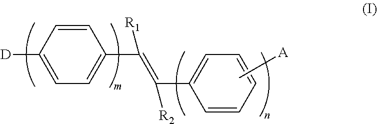

Here, m is an integer ranging from 0 to 5, n is an integer ranging from 0 to 5.

Each of R1 and R2 is independently selected from the group consisting of hydrogen, C₁ to C₆ alkyl group, aryl group, wherein the aryl group of R1 and R2 is C5 to C8, preferably.

The chemical formula of conjugated aromatic derivatives of the present invention may be represented by formula (II) to (IV):

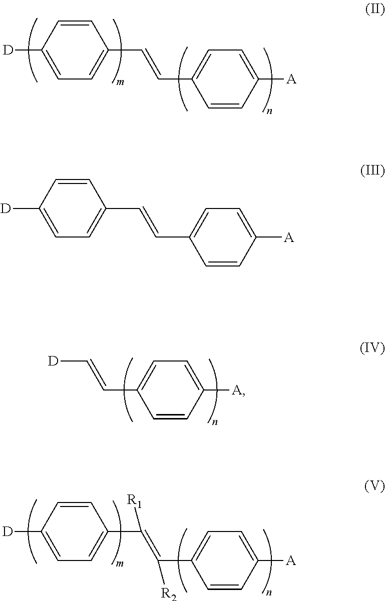

Substituent A denotes electron accepting group. When n=1 to 5, substituent A is selected from the group consisting of substituted or unsubstituted pyrene, substituted or unsubstituted phosphine oxide, substituted or unsubstituted sulfonyl and substituted or unsubstituted benzothiadiazole.

When n=0, substituent A is substituted or unsubstituted benzothiadiazole.

Some examples of substituent A are listed as follows, such as pyrene, diphenyl phosphine oxide, phenyl sulfonyl and phenyl benzothiadiazole.

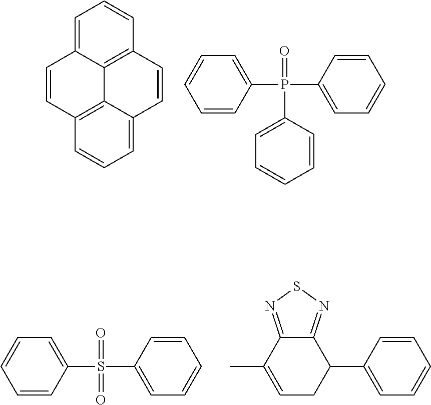

Substituent D denotes electron donating group.

When m=1 to 5, substituent D is selected from the group consisting of substituted or unsubstituted amino group, substituted or unsubstituted imidazole, substituted or unsubstituted carbazole and substituted or unsubstituted

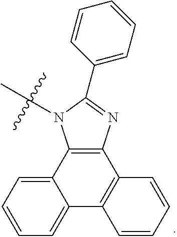 [SMILES: *n1c(-c2ccccc2)nc2c3ccccc3c3ccccc3c21]

When m=0, substituent D is substituted or unsubstituted

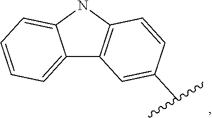 [SMILES: *c1ccc2[nH]c3ccccc3c2c1]

substituted or unsubstituted

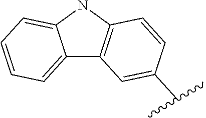 [SMILES: *c1ccc2[nH]c3ccccc3c2c1]

or, substituted or unsubstituted

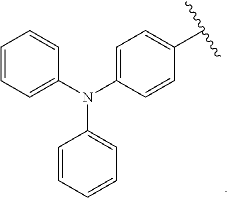 [SMILES: *c1ccc(N(c2ccccc2)c2ccccc2)cc1]

In one embodiment, substituent D is selected from the group consisting of follows:

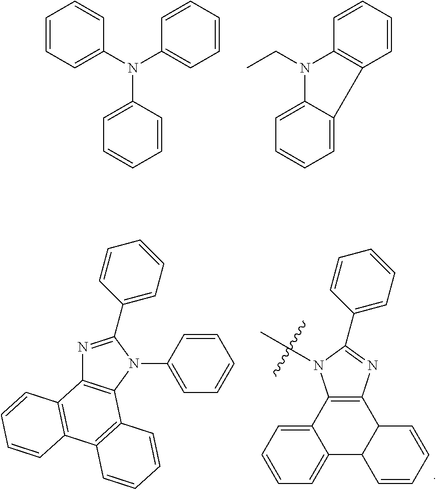

Each of the substituents of substituent D or substituent A is independently selected from the group consisting of halogen, aryl group, C₁-C₂₀ alkenyl, C₁-C₂₀ alkyl, C₁-C₂₀ alkynyl, cyano, CF₃, alkylamino, amino, alkoxy, heteroaryl, halogen substituted aryl group, halogen substituted aralkyl group, haloalkyl substituted aryl group, haloalkyl substituted aralkyl group, aryl substituted C₁-C₂₀ alkyl group, cycloalkyl group, C₁-C₂₀ alkoxy group, C₁-C₂₀ alkyl substituted amino group, haloalkyl substituted amino group, aryl substituted amino group, heteroaryl substituted amino group, aryl substituted phosphine oxide, C₁-C₂₀ alkyl substituted phosphine oxide, haloalkyl substituted phosphine oxide, halogen substituted phosphine oxide, heteroaryl substituted phosphine oxide, nitro group, carbonyl group, aryl substituted carbonyl group, heteroaryl substituted carbonyl group and halogen substituted C₁-C₂₀ alkyl group.

The term “aryl” refers to a C₆ to C₃₀ hydrocarbon moiety having one or more aromatic rings. Examples of aryl moieties include phenyl (Ph), phenylene, naphthyl, naphthylene, pyrenyl, anthryl, and phenanthryl.

The term “heteroaryl” refers to a C₅ to C₁₀ moiety having one or more aromatic rings that contain at least one heteroatom (e.g., N, O, or S). Examples of heteroaryl moieties include furyl, furylene, fluorenyl, pyrrolyl, thienyl, oxazolyl, imidazolyl, thiazolyl, pyridyl, pyrimidinyl, quinazolinyl, quinolyl, isoquinolyl and indolyl.

Alkyl, alkenyl, alkynyl, cycloalkyl, cycloalkenyl, heterocycloalkyl, heterocycloalkenyl, aryl, and heteroaryl mentioned herein include both substituted and unsubstituted moieties, unless specified otherwise. Possible substituents on cycloalkyl, cycloalkenyl, heterocycloalkyl, heterocycloalkenyl, aryl, and heteroaryl include, but are not limited to, C₁-C₁₀ alkyl, C₂-C₁₀ alkenyl, C₂-C₁₀ alkynyl, C₃-C₂₀ cycloalkyl, C₃-C₂₀ cycloalkenyl, C₁-C₂₀ heterocycloalkyl, C₁-C₂₀ heterocycloalkenyl, C₁-C₁₀ alkoxy, aryl, aryloxy, heteroaryl, heteroaryloxy, amino, C₁-C₁₀ alkylamino, C₁-C₂₀ dialkylamino, arylamino, diarylamino, C₁-C₁₀ alkylsulfonamino, arylsulfonamino, C₁-C₁₀ alkylimino, arylimino, C₁-C₁₀ alkylsulfonimino, arylsulfonimino, hydroxyl, halo, thio, C₁-C₁₀ alkylthio, arylthio, C₁-C₁₀ alkylsulfonyl, arylsulfonyl, acylamino, aminoacyl, aminothioacyl, amido, amidino, guanidine, ureido, thioureido, cyano, nitro, nitroso, azido, acyl, thioacyl, acyloxy, carboxyl, and carboxylic ester. On the other hand, possible substituents on alkyl, alkenyl, or alkynyl include all of the above-recited substituents except C₁-C₁₀ alkyl. Cycloalkyl, cycloalkenyl, heterocycloalkyl, heterocycloalkenyl, aryl, and heteroaryl can also be fused with each other.

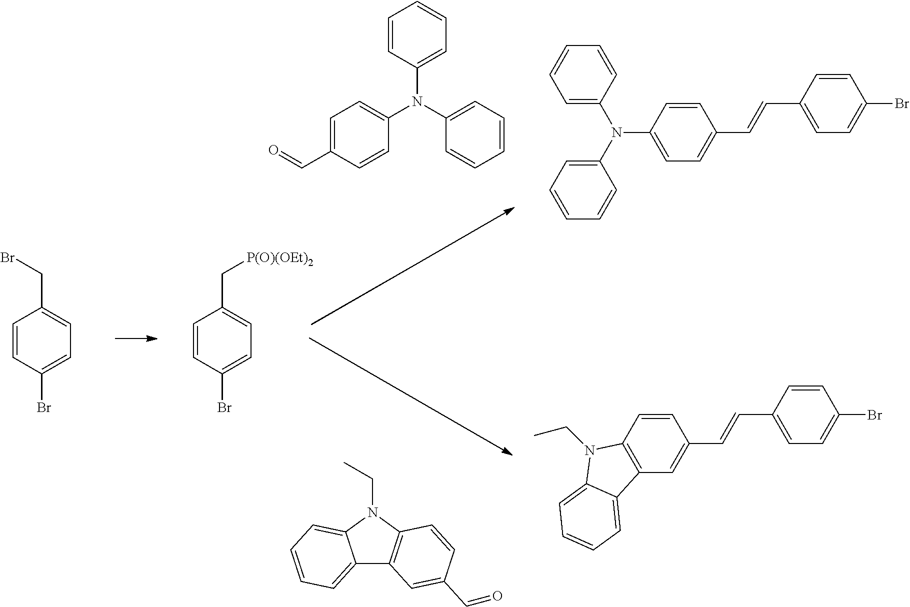

Refer to the above scheme illustrating the synthesis of compounds of the present invention, wherein substituent D of the formula of the present invention correspond to an amine group and a carbazole group.

It is noted that the substituent D of derivatives having different number of benzene rings may be obtained by adjusting the correspondent number of benzene rings of the starting material 1-bromo-4-(bromomethyl)benzene.

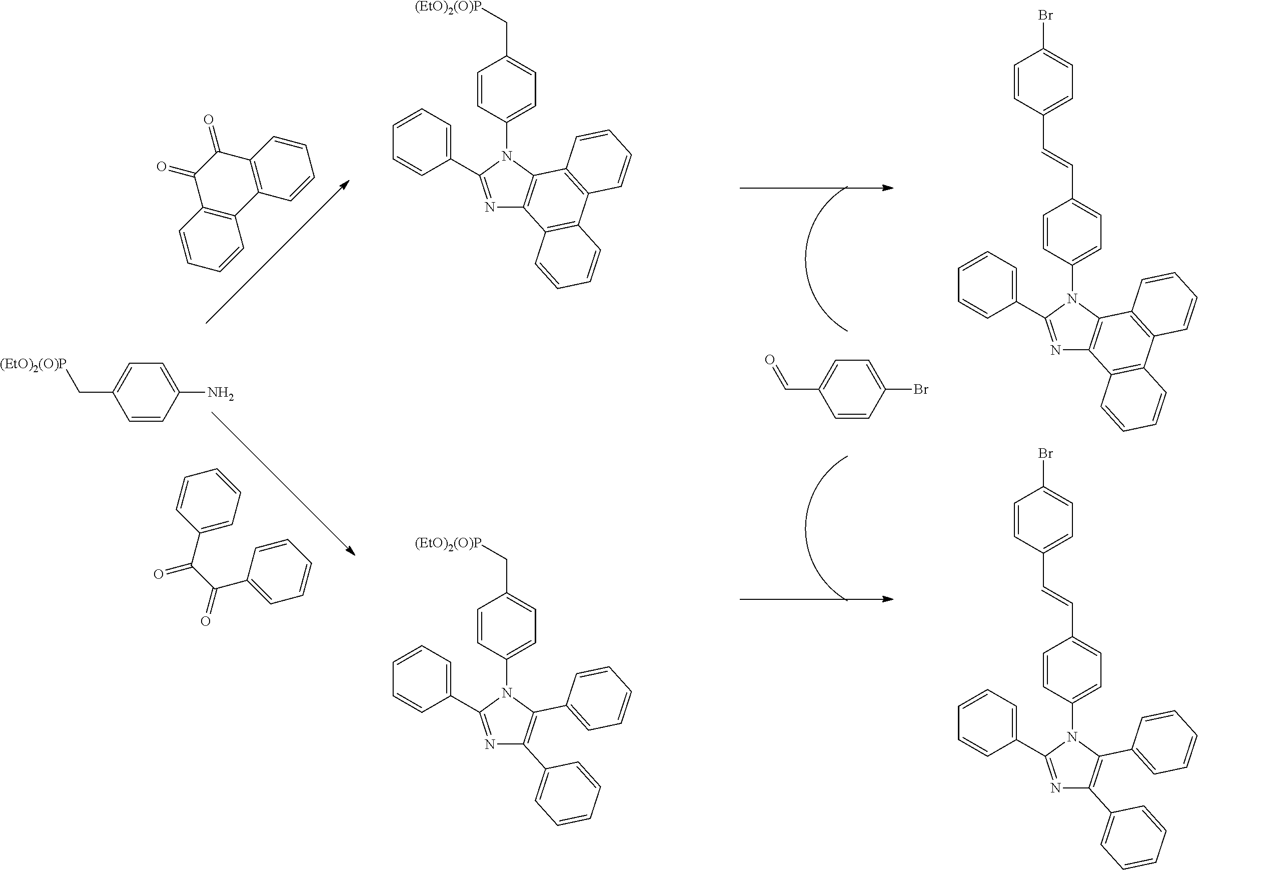

Refer to the above scheme illustrating the synthesis of compounds of the present invention, wherein substituent D of the formula of the present invention corresponds to a carbazole group or

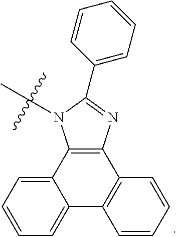 [SMILES: *n1c(-c2ccccc2)nc2c3ccccc3c3ccccc3c21]

It is noted that the substituent D of derivatives having different number of benzene rings may be obtained by adjusting the correspondent number of benzene rings of the starting material 4-bromobenzaldehyde.

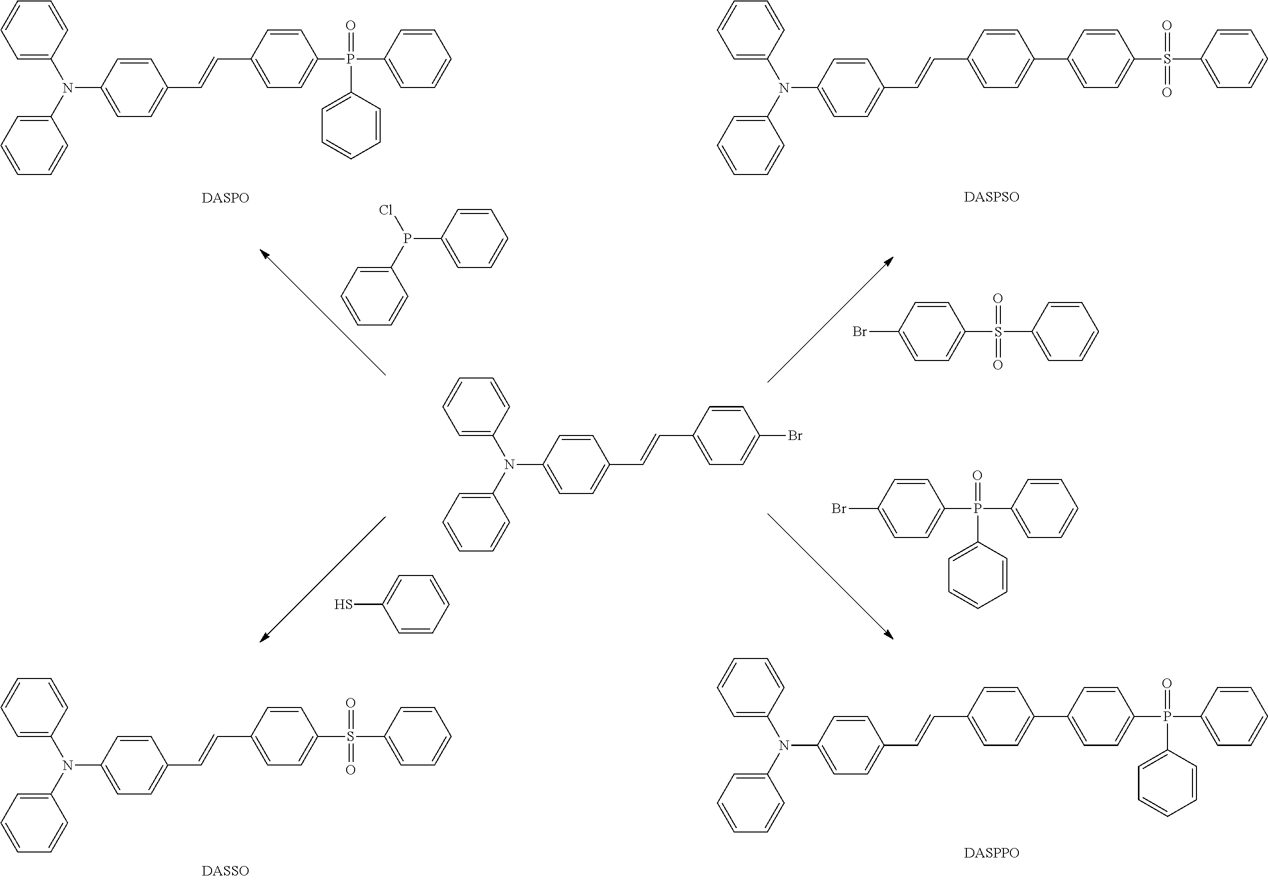

Some examples of the compounds of the present invention are listed as follows.

### (E)-(4-(4-(diphenylamino)styryl)phenyl)diphenylphosphine oxide (DASPO)

(E)-4-(4-bromostyryl)-N, N-diphenylaniline (0.43 g, 1 mmol) was added into the two-neck flask, followed by addition of THF 20 mL, and then cooled to −78° C. nBuLi (1.2 mmol) was added dropwise and stirred at low temperature for 1 hour. Chlorodiphenylphosphine (0.19 ml, 1 mmol) was slowly added and slowly warmed to room temperature for 8 hours reaction. Hydrochloric acid solution (2M) was then added. The mixture was then extracted with dichloromethane, and the organic layer were oxidized by adding hydrogen peroxide under an ice bath for 8 hours, then extracted with dichloromethane. The solvent was removed and purified by column chromatography to obtain the product (63%).

¹H NMR (400 MHz, CDCl₃), δ (ppm): 7.69-7.60 (m, 6H) 7.58-7.51 (m, 3H) 7.47-7.43 (m, 3H) 7.36 (d, J=8.0, 2H) 7.28-7.22 (m, 5H) 7.15-7.08 (m, 5H) 7.07-6.94 (m, 6H)

### (E)-(4′-(4-(diphenylamino)styryl)-[1,1′-biphenyl]-4-yl)diphenylphosphine oxide (DASPPO)

(E)-(4-(4-(diphenylamino) styryl)phenyl) boronic acid (0.94 g, 2.4 mmol), (4-bromophenyl)diphenylphosphine oxide (0.71 g, 2.0 mmol), Pd(PPh₃)₄ (0.1 g, 5 mol %), potassium carbonate (0.97 g) were added into 25 ml two-necked flask and toluene 10.5 ml, EtOH 3.5 ml, DI water 3.5 ml were added into flask, then heated to 90 degrees for 12 hour reaction. After completion of reaction, the solvent was removed and the reactants was filtered with Celite and purified by column chromatography to obtain the product (73%).

¹H NMR (400 MHz, CDCl₃), δ (ppm): 7.74-7.67 (m, 8H), 7.6-7.52 (m, 6H) 7.49-7.44 (m, 4H) 7.38 (d, J=8.0, 2H) 7.27-7.22 (m, 4H) 7.13-7.08 (m, 4H) 7.06-6.98 (m, 6H)

### (E)-N,N-diphenyl-4-(4-(phenylsulfonyl)styryl)aniline (DASSO)

(E)-4-(4-bromostyryl)-N, N-diphenylaniline (0.21 g, 0.5 mmol), thiophenol (0.056 mL, 0.55 mmol), NaOtBu (0.21 g, 2.2 mmol), Pd(PPh₃)₄ (0.058 g, 1 mol %), PPh₃ (0.052 g, 0.2 mmol), BuOH (30 mL) were placed into a two-neck flask and heated to reflux for 18 hours. The reactant was filtered with Celite and solvent were removed by rotary evaporation, and then purified by flash column chromatography. The collected compound was dissolved in acetic acid and hydrogen peroxide was added to undergo oxidation reaction for 5 hours, and the crude was then purified by column chromatography to obtain the product (65%).

¹H NMR (400 MHz, CDCl₃), δ (ppm): 7.95-7.93 (m, 2H), 7.88 (d, J=8.0, 2H) 7.56-7.46 (m, 5H) 7.35 (d, J=8.0, 2H) 7.29-7.23 (m, 4H) 7.14-7.08 (m, 5H) 7.06-6.91 (m, 5H)

### (E)-N,N-diphenyl-4-(2-(4′-(phenylsulfonyl)-[1,1′-biphenyl]-4-yl)vinyl)aniline (DASPSO)

Similar with the synthesis method of DASPPO, (4-bromophenyl)diphenylphosphine oxide was replaced with 1-bromo-4-(phenylsulfonyl)benzene, yield=70%.

¹H NMR (400 MHz, CDCl₃), δ (ppm): 8.00-7.96 (m, 4H) 7.72-7.69 (m, 2H) 7.58-7.49 (m, 7H) 7.38 (d, J=8.0, 2H) 7.27-7.22 (m, 4H) 7.12-6.97 (m, 10H)

### (E)-(4-(2-(9-ethyl-9H-carbazol-3-yl)vinyl)phenyl)diphenylphosphine oxide (CzSPO)

Similar with the synthesis method of DASPO, (E)-4-(4-bromostyryl)-N, N-diphenylaniline was replaced with (E)-3-(4-bromostyryl)-9-ethyl-9H-carbazole, yield=60%.

¹H NMR (400 MHz, CDCl₃), δ (ppm): 8.23 (s, 1H) 8.11 (d, J=8.0, 1H) 7.71-7.61 (m, 8H) 7.56-7.52 (m, 2H) 7.48-7.44 (m, 4H) 7.42-7.37 (m, 4H) 7.25-7.11 (m, 3H) 4.36 (q, J=8.0, 4.0, 2H) 1.41 (t, J=4.0, 3H)

### (E)-(4′-(2-(9-ethyl-9H-carbazol-3-yl)vinyl)-[1,1′-biphenyl]-4-yl)diphenylphosphine oxide (CzSPPO)

Similar with DASPPO synthesis method, (E)-(4-(4-(diphenylamino) styryl)phenyl) boronic acid was replaced with (E)-(4-(2-(9-ethyl-9H-carbazol-3-yl) vinyl)phenyl) boronic acid, yield=66%.

¹H NMR (400 MHz, CDCl₃), δ (ppm): 8.24 (s, 1H), 8.12 (d, J=8.0, 1H), 7.76-7.60 (m, 12H) 7.57-7.53 (m, 2H) 7.49-7.45 (m, 4H) 7.41-7.35 (m, 4H) 7.26-7.15 (m, 3H) 4.36 (q, J=8.0, 4.0, 2H) 1.43 (t, J=8.0, 3H)

### (E)-9-ethyl-3-(4-(phenylsulfonyl)styryl)-9H-carbazole (CzSSO)

Similar with DASSO synthesis method, (E)-4-(4-bromostyryl)-N, N-diphenylaniline replaced with (E)-3-(4-bromostyryl)-9-ethyl-9H-carbazole, yield=66%.

¹H NMR (400 MHz, CDCl₃), δ (ppm): 8.22 (s, 1H) 8.10 (d, J=8.0, 1H) 7.96-7.89 (m, 4H) 7.66-7.61 (m, 3H) 7.57-7.45 (m, 3H) 7.41-7.37 (m, 3H) 7.26-7.08 (m, 3H) 4.35 (q, J=8.0, 4.0, 2H) 1.43 (t, J=8.0, 3H)

### (E)-9-ethyl-3-(2-(4′-(phenylsulfonyl)-[1,1′-biphenyl]-4-yl)vinyl)-9H-carbazole (CzSPSO)

Similar with CzSPPO synthesis method, (4-bromophenyl)diphenylphosphine oxide was replaced with 1-bromo-4-(phenylsulfonyl)benzene, yield=70%.

¹H NMR (400 MHz, CDCl₃), δ (ppm): 8.23 (s, 1H) 8.12 (d, J=8.0, 1H) 8.00-7.96 (m, 3H) 7.74-7.71 (m, 2H) 7.67 (dd, J=8.0, 1.2, 1H) 7.64-7.45 (m, 8H) 7.41-7.35 (m, 3H) 7.26-7.13 (m, 3H) 4.37 (q, J=8.0, 4.0, 2H) 1.44 (t, J=8.0, 3H)

### (E)-1-(4-(2-(9-ethyl-9H-carbazol-3-yl)vinyl)phenyl)-2-phenyl-1H-phenanthro[9,10-d]imidazole (PISCz)

(4-(2-phenyl-1H-phenanthro[9,10-d]imidazol-1-yl)benzyl)phosphonate (1.04 g, 2 mmol) and 4-(diphenylamino)benzaldehyde (0.55 g, 2 mmol) were dissolved in THF (10 ml). The mixture were then added dropwise to a solution of THF containing KOtBu (0.45 g, 4 mmol), and the mixture were reacted for 8 hours. The reaction was then poured into a large amount of water, and the precipitated was then filtered, recrystallized yield=35%.

¹H NMR (400 MHz, CDCl₃), δ (ppm): 8.86 (d, J=8.0, 1H) 8.76 (d, J=8.0, 1H) 8.70 (d, J=8.0, 1H) 8.28 (s, 1H) 8.14 (d, J=8.0, 1H) 7.75-7.71 (m, 4H) 7.66-7.62 (m, 3H) 7.53-7.41 (m, 6H) 7.36-7.23 (m, 8H) 4.39 (q, J=8.0, 4.0, 2H) 1.46 (t, J=8.0, 3H)

### (E)-N,N-diphenyl-4-(4-(2-phenyl-1H-phenanthro[9,10-d]imidazol-1-yl)styryl)aniline (PISDA)

Similar with PISCz, the 4-(diphenylamino)benzaldehyde was replaced by 9-ethyl-9H-carbazole-3-carbaldehyde, yield=40%.

¹H NMR (400 MHz, CDCl₃), δ (ppm): 8.86 (d, J=8.0, 1H) 8.76 (d, J=8.0, 1H) 8.69 (d, J=8.0, 1H) 7.72 (t, J=8.0, 1H) 7.68-7.59 (m, 4H) 7.52 (m, 1H) 7.46-7.41 (m, 3H) 7.32-7.22 (m, 10H) 7.17-7.03 (m, 11H)

TABLE 1
The absorbance and emission spectrum of
the compounds of the present invention

| | λ_{abs} in Tol | λₑₘ in Tol | λ_{abs} in | λₑₘ in | Q · Y in |
|---|---|---|---|---|---|
| | (nm) | (nm) | film (nm) | film (nm) | solution |
| DASPO | 285, 382 | 445 | 304, 396 | 484 | 45.7% |
| DASPPO | 300, 384 | 447 | 308, 396 | 493 | 64.5% |
| DASSO | 303, 391 | 459 | 306, 409 | 509 | 30.6% |
| DASPSO | 301, 391 | 460 | 302, 400 | 504 | 62.0% |
| CzSPO | 308, 353 | 420 | 305, 366 | 477 | 11.1% |
| CzSPPO | 298, 356 | 425, 444 | 303, 363 | 478 | 42.7% |
| CzSSO | 298, 357 | 440 | 303, 384 | 500 | 7.4% |
| CzSPSO | 300, 363 | 447 | 302, 371 | 508 | 58.1% |

Refer to Table 1, which illustrates the absorbance and emission spectrum of the compounds of the present invention, where the conjugated aromatic derivatives are blue light-emitter.

TABLE 2
The glass transition temperature and decomposition
temperature of the compounds of the present invention

| Compound | T_{g} (° C.) | T _{d}(° C.) |
|---|---|---|
| DASPO | 70 | 435 |
| DASSO | 73 | 414 |
| CzSPO | 70 | 424 |
| CzSSO | 80 | 420 |
| DASPPO | 96 | 471 |
| DASPSO | 86 | 464 |
| CzSPPO | 100 | 464 |
| CzSPSO | — | 454 |

Refer to Table 2, which illustrates the glass transition temperature and decomposition temperature of the compounds of the present invention, where the conjugated aromatic derivatives of the present invention are provided with excellent thermal stability.

TABLE 3
The singlet and triplet energy of the
compounds of the present invention

| Compound | E_{S} (eV) | E_{T} (eV) | ΔE_{ST} (eV) |
|---|---|---|---|
| DASPO | 2.84 | 2.58 | 0.26 |
| DASSO | 2.75 | 2.66 | 0.09 |
| DASPPO | 2.81 | 2.58 | 0.23 |
| DASPSO | 2.77 | 2.67 | 0.10 |
| CzSPO | 2.91 | 2.77 | 0.14 |
| CzSSO | 2.83 | 2.72 | 0.11 |
| CzSPPO | 2.82 | 2.75 | 0.07 |
| CzSPSO | 2.79 | 2.75 | 0.04 |

Refer to Table 3, which illustrates the singlet and triplet energy of the compounds of the present invention, where the conjugated aromatic derivatives of the present invention are provided with excellent energy gap between singlet and triplet.

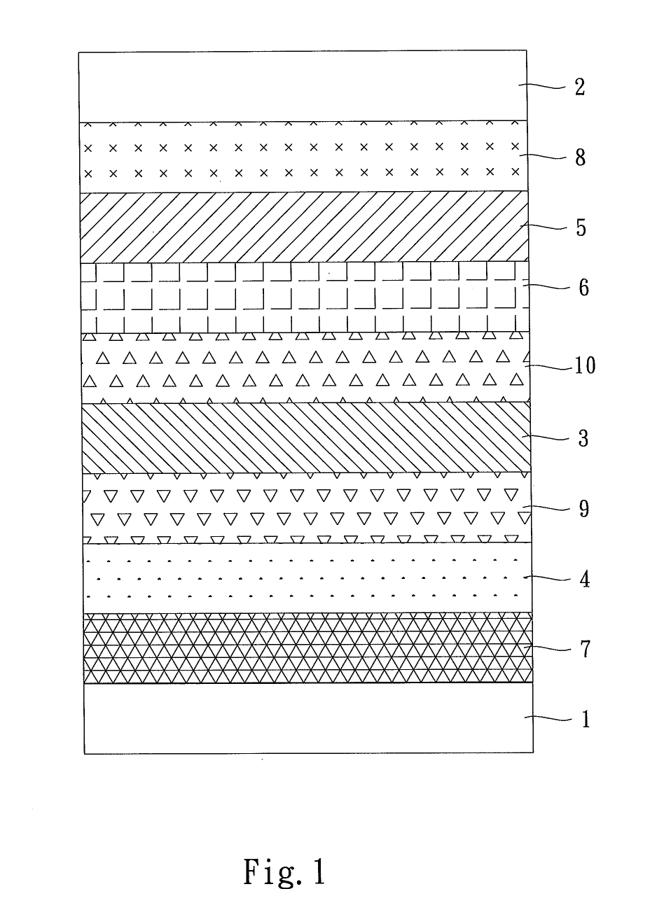

Refer to FIG. 1, which is a schematic diagram illustrating an organic light emitting device containing conjugated aromatic derivatives according to one embodiment of the present invention. The light emitting device includes an emitting layer 3 configured between the anode 1 and cathode 2. The emitting layer 3 is made of host emitting material doped with light emitting material. The light emitting device may also include a hole injecting layer 7, a hole transport layer 4, an electron blocking layer 9, an emitting layer 3, an exciton blocking layer 10, a hole blocking layer 6, an electron transport layer 5 and an electron injecting layer 8 sequentially configured on top of the anode 1. The real thickness of each layer doesn't correspond to the schematic size, and exciton blocking layer 10, electron blocking layer 9, hole blocking layer 6 and electron injecting layer 8 may be optional. The conjugated aromatic derivatives of the present invention may function as a host emitter or a guest emitter in the emitting layer, or the conjugated aromatic derivatives of the present invention may function as an electron transport material or an electron injection material.

In the tested electroluminescent devices, the substrate is made of ITO; tested electrode materials include LiF/Al; tested emitting materials include m-PPT (2-3-(pyren-1-yl)phenyl)triphenylene); the test electron transport materials include BCP (2,9-dimethyl-4,7-diphenyl-[1,10]phenanthroline) and Alq₃ (tris(8-hydroxyquinoline)aluminum(III) which can be used for the hole blocking layer or simultaneous hole stopper layer and electron transport layer. The test hole transporting materials include NPB (4,4′-bis[N-(1-naphthyl)-N-phenyl-amino]bipheny), and TCTA (Tris(4-carbazoyl-9-ylphenyl)amine), which can be used for the hole blocking layer or simultaneous electron blocking layer and hole transport layer.

The detailed structures of the tested devices are as follows:

1A:NPB(30)/TCTA(10)/m-PPT:PISDA(5%)(30)/BAlq(25)/LiF(1)/Al(100)
1B:NPB(30)/TCTA(10)/m-PPT:PISCz(5%)(30)/BAlq(25)/LiF(1)/Al(100)

### 2A:NPB(30)/MCP(20)/BCPO:PISDA(10%)(30)/TAZ(45)/LiF(1)/Al(100)

### 2B:NPB(30)/MCP(20)/BCPO:PISCz(10%)(30)/TAZ(45)/LiF(1)/Al(100)

TABLE 4
The performance of devices using the
compounds of the present invention

| | | | | | | EL | |
|---|---|---|---|---|---|---|---|
| | E.Q.E. | | | Lₘₐₓ | V_{d} | λₘₐₓ | |
| Device | (%) (V) | C.E. (cd/A) | P.E. (1 m/W) | (cd/m²) (V) | (V) | (nm) | CIE_{(x,y)} |
| 1A | 5.7 (11.5) | 7.0 | 3.6 | 19320 (20.0) | 3.7 | 462 | (0.14, 0.15) |
| 1B | 4.4 (11.0) | 5.9 | 2.0 | 16984 (20.0) | 4.0 | 466 | (0.14, 0.17) |
| 2A | 5.2 (5.0) | 5.1 | 3.2 | 6757 (20.0) | 4.7 | 452 | (0.14, 0.11) |
| 2B | 5.6 (4.5) | 3.0 | 2.1 | 4381 (20.0) | 4.3 | 434 | (0.15, 0.06) |

Lₘₐₓ: maximum luminescence;
E.Q.E.: maximum external quantum efficiency;
C.E.: maximum current efficiency;
P.E.: maximum power efficiency;
V_{d}: drive voltage;
λₘₐₓ: maximum emission wavelength.

Refer to Table 4 illustrating the device performance using the compounds of the present invention, wherein the external quantum efficiency of the apparatus 1B, 1D, 1H is greater than 8.0 and reaches 8.9, 8.3 and 8.6, respectively.

In another embodiment, the detailed structures of the tested devices are as follows:

### 2A:NPB(30)/MCP(20)/BCPO:DASPO(10%)(30)/TAZ(45)/LiF(1)/Al(100)

### 2B:NPB(30)/MCP(20)/BCPO:DASPPO(10%)(30)/TAZ(45)/LiF(1)/Al(100)

### 2C:NPB(30)/MCP(20)/BCPO:DASSO(10%)(30)/TAZ(45)/LiF(1)/Al(100)

### 2D:NPB(30)/MCP(20)/BCPO:DASPSO(10%)(30)/TAZ(45)/LiF(1)/Al(100)

### 2E:NPB(30)/MCP(20)/BCPO:CzSPO(10%)(30)/TAZ(45)/LiF(1)/Al(100)

### 2F:NPB(30)/MCP(20)/BCPO:CzSPPO(10%)(30)/TAZ(45)/LiF(1)/Al(100)

### 2G:NPB(30)/MCP(20)/BCPO:CzSSO(10%)(30)/TAZ(45)/LiF(1)/Al(100)

### 2H:NPB(30)/MCP(20)/BCPO:CzSPSO(10%)(30)/TAZ(45)/LiF(1)/Al(100)

TABLE 5
The performance of devices using the
compounds of the present invention

| | | C.E. | P.E. | | | EL | |
|---|---|---|---|---|---|---|---|
| De- | E.Q.E. | (cd/ | (1 m/ | Lₘₐₓ | V_{d} | λₘₐₓ | |
| vice | (%) (V) | A) | W) | (cd/m²) (V) | (V) | (nm) | CIE_{(x,y)} |
| 2A | 4.9 (5.5) | 8.3 | 4.4 | 8745 (20.0) | 5.1 | 468 | (0.15, 0.20) |
| 2B | 7.9 (4.0) | 10.8 | 8.5 | 13501 (20.0) | 3.7 | 462 | (0.14, 0.17) |
| 2C | 8.7 (5.0) | 18.4 | 11.6 | 7945 (20.0) | 4.7 | 490 | (0.15, 0.37) |
| 2D | 7.9 (4.0) | 15.1 | 11.9 | 15481 (20.0) | 3.9 | 478 | (0.15, 0.28) |
| 2E | 3.3 (5.0) | 2.8 | 1.8 | 4211 (20.0) | 5.0 | 452 | (0.15, 0.10) |
| 2F | 8.0 (4.0) | 7.8 | 6.1 | 10662 (19.0) | 3.5 | 456 | (0.14, 0.11) |
| 2G | 4.9 (4.5) | 6.3 | 4.4 | 7588 (20.0) | 4.3 | 452 | (0.14, 0.16) |
| 2H | 9.3 (4.0) | 13.9 | 10.9 | 20207 (20.0) | 3.6 | 466 | (0.14, 0.19) |

Refer to Table 5, which illustrates the device performance using the compounds of the present invention, wherein the external quantum efficiency of the device 2C, 2F, 2H is greater than 8.0, and reaches 8.7, 8.0 and 9.3, respectively.

It was found recently that smaller gap between singlet and triplet energy levels may increase the likelihood of forming thermally activated delayed fluorescence (TADF), and the internal quantum efficiency of fluorescence may reach 100%, which is the same as phosphorescent emitters. It is therefore these compounds may greatly improve luminous efficacy and are very different from conventional fluorescent emitters having only 25% performance.

In summary, the conjugated aromatic derivatives of the present invention are provided with an electron donating group and an electron accepting group at each end. The conjugated aromatic derivatives of the present invention has a blue light-emitting property, and may be used as main material, electron transport material or hole transport material. OLED devices using the conjugated aromatic derivatives of the present invention are also provided with good performance.

While the invention can be subject to various modifications and alternative forms, a specific example thereof has been shown in the drawings and is herein described in detail. It should be understood, however, that the invention is not to be limited to the particular form disclosed, but on the contrary, the invention is to cover all modifications, equivalents, and alternatives falling within the spirit and scope of the appended claims.

What is claimed is:

1. A conjugated aromatic derivative having a chemical formula represented by formula (I): 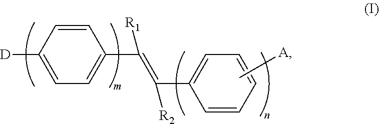
wherein m is an integer ranging from 0 to 5, n is an integer ranging from 0 to 5, each of R1 and R2 is independently selected from the group consisting of hydrogen, C₁ to C₆ alkyl group, aryl group,
when n=1 to 5, substituent A is selected from the group consisting of substituted or unsubstituted pyrene, substituted or unsubstituted phosphine oxide, substituted or unsubstituted sulfonyl and substituted or unsubstituted benzothiadiazole;
when n=0, substituent A is substituted or unsubstituted benzothiadiazole; and
when m=1 to 5, substituent D is selected from the group consisting of substituted or unsubstituted amino group, substituted or unsubstituted imidazole, substituted or unsubstituted carbazole and substituted or unsubstituted 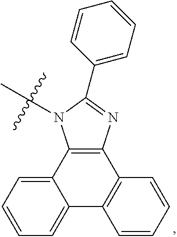 [SMILES: *n1c(-c2ccccc2)nc2c3ccccc3c3ccccc3c21]
when m=0, substituent D is substituted or unsubstituted 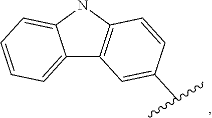 [SMILES: *c1ccc2[nH]c3ccccc3c2c1]
substituted or unsubstituted 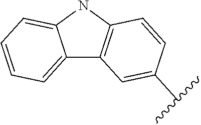 [SMILES: *c1ccc2[nH]c3ccccc3c2c1]
or, substituted or unsubstituted 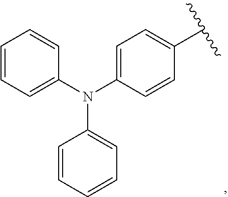 [SMILES: *c1ccc(N(c2ccccc2)c2ccccc2)cc1]
wherein each of the substituents of substituent D or substituent A is independently selected from the group consisting of halogen, aryl group, C₁-C₂₀ alkenyl, C₁-C₂₀ alkyl, C₁-C₂₀ alkynyl, cyano, CF₃, alkylamino, amino, alkoxy, heteroaryl, halogen substituted aryl group, halogen substituted aralkyl group, haloalkyl substituted aryl group, haloalkyl substituted aralkyl group, aryl substituted C₁-C₂₀ alkyl group, cycloalkyl group, C₁-C₂₀ alkoxy group, C₁-C₂₀ alkyl substituted amino group, haloalkyl substituted amino group, aryl substituted amino group, heteroaryl substituted amino group, aryl substituted phosphine oxide, C₁-C₂₀ alkyl substituted phosphine oxide, haloalkyl substituted phosphine oxide, halogen substituted phosphine oxide, heteroaryl substituted phosphine oxide, nitro group, carbonyl group, aryl substituted carbonyl group, heteroaryl substituted carbonyl group and halogen substituted C₁-C₂₀ alkyl group.

2. The conjugated aromatic derivative as claimed in claim 1 having a chemical formula represented by formula (II):

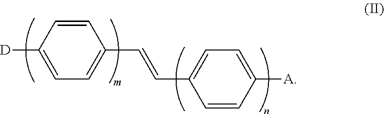

3. The conjugated aromatic derivative as claimed in claim 1 having a chemical formula represented by formula (III):

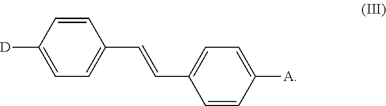

4. The conjugated aromatic derivative as claimed in claim 1 having a chemical formula represented by formula (IV): 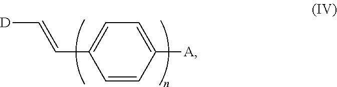
wherein substituent D is selected from the group consisting of follows:

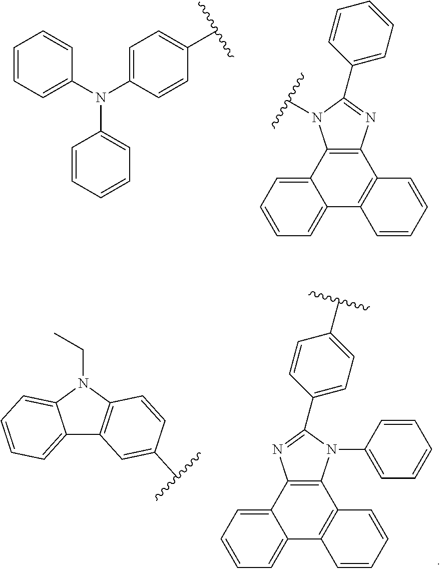 [SMILES: *c1ccc(N(c2ccccc2)c2ccccc2)cc1 ; *n1c(-c2ccccc2)nc2c3ccccc3c3ccccc3c21 ; *c1ccc2c(c1)c1ccccc1n2CC ; *c1ccc(-c2nc3c4ccccc4c4ccccc4c3n2-c2ccccc2)cc1]

5. The conjugated aromatic derivative as claimed in claim 1, wherein substituent A is selected from the group consisting of pyrene, diphenyl phosphine oxide, phenyl substituted sulfonyl and phenyl substituted benzothiadiazole.

6. The conjugated aromatic derivative as claimed in claim 1, wherein m is an integer ranging from 0 to 2, and n is an integer ranging from 0 to 2.

7. An organic light emitting diode, comprising:
a cathode;
an anode; and
an organic layer configured between the cathode and the anode and comprising a conjugated aromatic derivative having a chemical formula represented by Formula (I): 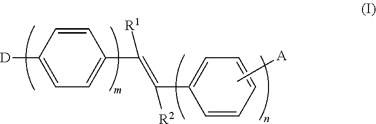
wherein m is an integer ranging from 0 to 5, n is an integer ranging from 0 to 5, each of R1 and R2 is independently selected from the group consisting of hydrogen, C₁ to C₆ alkyl group, aryl group,
when n=1 to 5, substituent A is selected from the group consisting of substituted or unsubstituted pyrene, substituted or unsubstituted phosphine oxide, substituted or unsubstituted sulfonyl and substituted or unsubstituted benzothiadiazole; when n=0, substituent A is substituted or unsubstituted benzothiadiazole; and
when m=1 to 5, substituent D is selected from the group consisting of substituted or unsubstituted amino group, substituted or unsubstituted imidazole, substituted or unsubstituted carbazole and substituted or unsubstituted 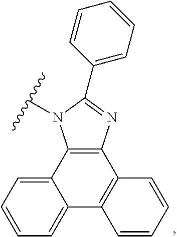 [SMILES: *n1c(-c2ccccc2)nc2c3ccccc3c3ccccc3c21]
when m=0, substituent D is substituted or unsubstituted 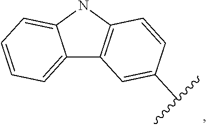 [SMILES: *c1ccc2[nH]c3ccccc3c2c1]
substituted or unsubstituted 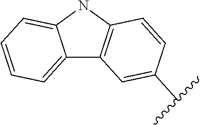 [SMILES: *c1ccc2[nH]c3ccccc3c2c1]
or, substituted or unsubstituted 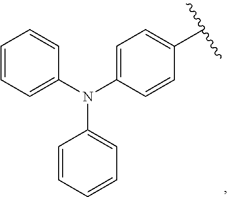 [SMILES: *c1ccc(N(c2ccccc2)c2ccccc2)cc1]
wherein each of the substituents of substituent D or substituent A is independently selected from the group consisting of halogen, aryl group, C₁-C₂₀ alkenyl, C₁-C₂₀ alkyl, C₁-C₂₀ alkynyl, cyano, CF₃, alkylamino, amino, alkoxy, heteroaryl, halogen substituted aryl group, halogen substituted aralkyl group, haloalkyl substituted aryl group, haloalkyl substituted aralkyl group, aryl substituted C₁-C₂₀ alkyl group, cycloalkyl group, C₁-C₂₀ alkoxy group, C₁-C₂₀ alkyl substituted amino group, haloalkyl substituted amino group, aryl substituted amino group, heteroaryl substituted amino group, aryl substituted phosphine oxide, C₁-C₂₀ alkyl substituted phosphine oxide, haloalkyl substituted phosphine oxide, halogen substituted phosphine oxide, heteroaryl substituted phosphine oxide, nitro group, carbonyl group, aryl substituted carbonyl group, heteroaryl substituted carbonyl group and halogen substituted C₁-C₂₀ alkyl group.

8. The organic light emitting diode as claimed in claim 7, wherein the conjugated aromatic derivative has a chemical formula represented by formula (II):

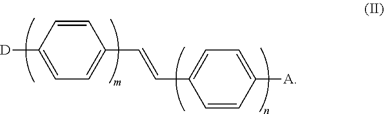

9. The organic light emitting diode as claimed in claim 7, wherein the conjugated aromatic derivative has a chemical formula represented by formula (III):

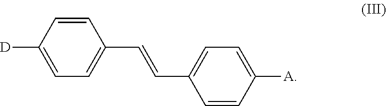

10. The organic light emitting diode as claimed in claim 7, wherein the conjugated aromatic derivative has a chemical formula represented by formula (IV), 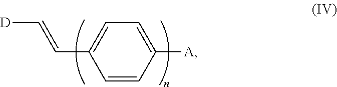
wherein substituent D is selected from the group consisting of follows:

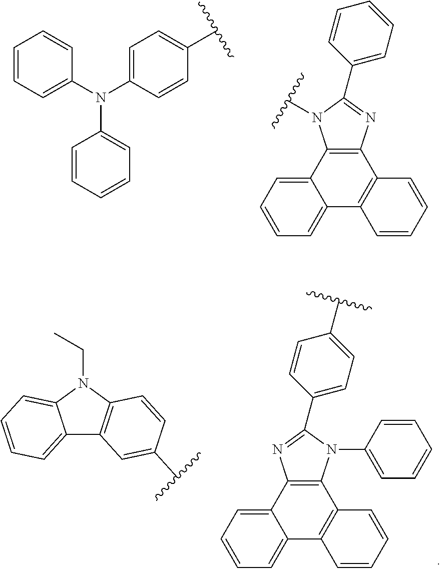 [SMILES: *c1ccc(N(c2ccccc2)c2ccccc2)cc1 ; *n1c(-c2ccccc2)nc2c3ccccc3c3ccccc3c21 ; *c1ccc2c(c1)c1ccccc1n2CC ; *c1ccc(-c2nc3c4ccccc4c4ccccc4c3n2-c2ccccc2)cc1]

11. The organic light emitting diode as claimed in claim 7, wherein substituent A is selected from the group consisting of pyrene, diphenyl phosphine oxide, phenyl substituted sulfonyl and phenyl substituted benzothiadiazole.

12. The organic light emitting diode as claimed in claim 7, wherein m is an integer ranging from 0 to 2, and n is an integer ranging from 0 to 2.

13. The organic light emitting diode as claimed in claim 7, being a blue phosphorescent OLED.

14. The organic light emitting diode as claimed in claim 7, wherein the conjugated aromatic derivative is a guest emitter.

15. The organic light emitting diode as claimed in claim 7, wherein the conjugated aromatic derivative is a host emitter.

16. The organic light emitting diode as claimed in claim 7, wherein the organic layer is an electron transport layer and the conjugated aromatic derivative is an electron transport material.

17. The organic light emitting diode as claimed in claim 7, wherein the organic layer is a hole transport layer and the conjugated aromatic derivative is a hole transport material.
